(19) United States
(12) Patent Application Publication
(10) Pub. No.: US 2012/0241814 A1
(43) Pub. Date: Sep. 27, 2012

(54) POWER SEMICONDUCTOR DEVICE

(75) Inventors: Shuji KAMATA, Hyogo-ken (JP); Masakazu Kobayashi, Hyogo-ken (JP)

(73) Assignee: Kabushiki Kaisha Toshiba, Tokyo (JP)

(21) Appl. No.: 13/425,250

(22) Filed: Mar. 20, 2012

(30) Foreign Application Priority Data
Mar. 23, 2011 (JP) 2011-064667

(51) Int. Cl. H01L 29/739

(52) U.S. Cl. 257/139; 257/E29.197

(57) ABSTRACT

A power semiconductor device includes a p-type collector layer, an n-type base layer, a p-type base layer, an n-type source layer, and a gate electrode. The gate electrode is formed in a trench running from a surface of the n-type source layer through the n-type source layer and the p-type base layer to an interior of the n-type base layer via a gate insulating film. The gate electrode includes a first portion and a second portion. The first portion is opposed to a bottom end portion of the p-type base layer. The second portion is opposed to an upper end portion of the p-type base layer. The gate electrode is formed such that a threshold at the bottom end portion of the p-type base layer is not less than a threshold at the upper end portion of the p-type base layer.

### CROSS-REFERENCE TO RELATED APPLICATION

This application is based upon and claims the benefit of priority from the prior Japanese Patent Application No. 2011-064667, filed on Mar. 23, 2011; the entire contents of which are incorporated herein by reference.

### FIELD

Embodiments described herein relate generally to a gate insulated type power semiconductor device.

### BACKGROUND

IGBTs (insulated gate bipolar transistors), IEGTs (injection enhanced gate transistors), etc. (hereinafter referred to as IGBTs etc.) are used as switching elements of power supply devices that drive automobiles, railway vehicles, industrial motors, etc. Since it is required for these power semiconductor devices to raise breakdown voltage, increase current, and reduce loss, a trench gate structure is used in which the channel density can be increased to reduce the ON resistance. In such a power supply device, if a short circuit accident occurs in a motor that is a load, all the large voltage that has been applied to the load is applied to the IGBT etc., and a large load short-circuit current flows through the IGBT etc. The time in which the load short-circuit current flows until the IGBT etc. are broken is called a load short-circuit withstand capability. In the power supply device for motor drive, a function is provided in which, when a load short circuit occurs, a sensor detects it to protect the IGBT etc. However, it requires a processing time of approximately 10 microseconds from when the load short circuit occurs to when the protection function therefor operates. Therefore, the IGBT etc. are required to have a load short-circuit withstand capability exceeding 10 microseconds sufficiently. However, in the IGBT etc., the channel density is increased to reduce the ON resistance. Since the load short-circuit current increases as the ON resistance decreases, there is a problem of a trade-off in which the load short-circuit withstand capability decreases. An IGBT or IEGT in which the ON resistance is reduced and at the same time the load short-circuit withstand capability is improved is desired.

### BRIEF DESCRIPTION OF THE DRAWINGS

FIG. 1 is a cross-sectional view of a main portion of a power semiconductor device according to a first embodiment.

FIG. 2 is a graph showing the impurity concentration profile along line C-C of FIG. 1.

FIG. 3 is a graph showing the change along the trench depth direction of the gate insulating film thickness of the power semiconductor device according to the first embodiment.

FIG. 4 is a cross-sectional view of a main portion of a power semiconductor device according to a comparative example.

FIG. 5 is a graph showing the change along the trench depth direction of the gate insulating film thickness of the power semiconductor device according to the comparative example.

FIG. 6 is a cross-sectional view of a main portion for describing operations of the power semiconductor device according to the comparative example.

FIG. 7 is a graph showing the profile of the p-type impurity concentration of a p-type base layer and the change in the depth direction of the threshold of the power semiconductor device according to the comparative example.

FIG. 8 is a graph showing relationships between the inter-gate/base voltage and the inter-collector/emitter current of the power semiconductor device according to the comparative example.

FIG. 9 is a graph showing the profile of the p-type impurity concentration of a p-type base layer and the change in the depth direction of the threshold of the power semiconductor device according to the first embodiment.

FIG. 10 is a graph showing relationships between the inter-gate/base voltage and the inter-collector/emitter current of the power semiconductor device according to the first embodiment.

FIG. 11 is a cross-sectional view of a main portion of a power semiconductor according to a modification example of the first embodiment.

FIG. 12 is a graph showing a change along a trench depth direction of a gate insulating film thickness of the power semiconductor device according to the modification example of the first embodiment.

FIG. 13 is a graph showing a profile of a p-type impurity concentration of a p-type base layer and a change in a depth direction of a threshold of the power semiconductor device according to the modification example of the first embodiment.

FIG. 14 is a graph showing relationships between a igate-base voltage and a collector-emitter current of the power semiconductor device according to the modification example of the first embodiment.

FIG. 15 is a cross-sectional view of a main portion of a power semiconductor device according to a second embodiment.

### DETAILED DESCRIPTION

A power semiconductor device includes a p-type collector layer, an n-type base layer, a p-type base layer, an n-type source layer, a gate electrode, an interlayer insulating film, a collector electrode, and an emitter electrode. The n-type base layer is formed on the p-type collector layer. The p-type base layer is formed on the n-type base layer. The n-type source layer selectively formed on a surface of the p-type base layer and has a higher n-type impurity concentration than the n-type base layer. The gate electrode is formed in a trench running from a surface of the n-type source layer through the n-type source layer and the p-type base layer to an interior of the n-type base layer via a gate insulating film. The interlayer insulating film is formed on the gate electrode. The collector electrode is electrically connected to a surface of the p-type collector layer on an opposite side to the n-type source layer. The emitter electrode is electrically connected to the n-type source layer and the p-type contact layer via an opening provided in the interlayer insulating film. An impurity concentration of the p-type base layer has a maximum in an upper end portion adjacent to the source layer and decrease from the upper end portion of the p-type base layer toward the n-type base layer in a stacking direction. The gate electrode includes a first portion and a second portion. The first portion of the gate electrode is opposed to the n-type base layer and a bottom end portion of the p-type base layer via a first portion of the gate insulating film. The second portion of the gate electrode is continuous with an upper portion of the first portion of the gate electrode and is opposed to the upper end portion of the p-type base layer and the n-type source layer via a second portion of the gate insulating film. The gate electrode is formed such that a threshold for a population inversion layer to be formed between the first portion of the gate insulating film and the bottom end portion of the p-type base layer is not less than a threshold for a population inversion layer to be formed between the second portion of the gate insulating film and the upper end portion of the p-type base layer.

Hereinbelow, embodiments of the invention are described with reference to the drawings. The drawings used in the description of the embodiments are schematic for easier description; and in the actual practice, the configurations, dimensions, magnitude relationships, etc. of the components in the drawings are not necessarily the same as those illustrated in the drawings and may be appropriately altered to the extent that the effect of the invention is obtained. Unless otherwise specified, the semiconductor material is described using silicon as an example. Furthermore, in the case where the n⁻ type, the n type, and the n⁺ type are used, it is assumed that the relationships of n⁻<n<n⁺ exist among the impurity concentrations thereof. This applies also to the p⁻ type, the p type, and the p⁺ type. Although the embodiments describe the power semiconductor device using an IGBT as an example, these embodiments can be similarly applied to an IEGT.

### First Embodiment

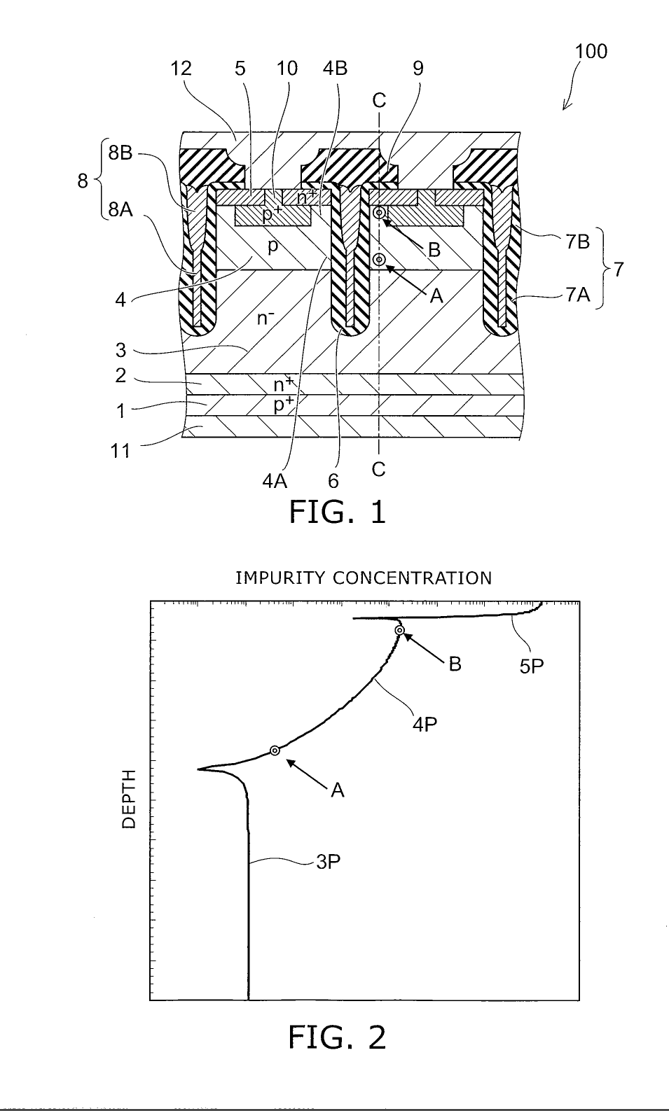

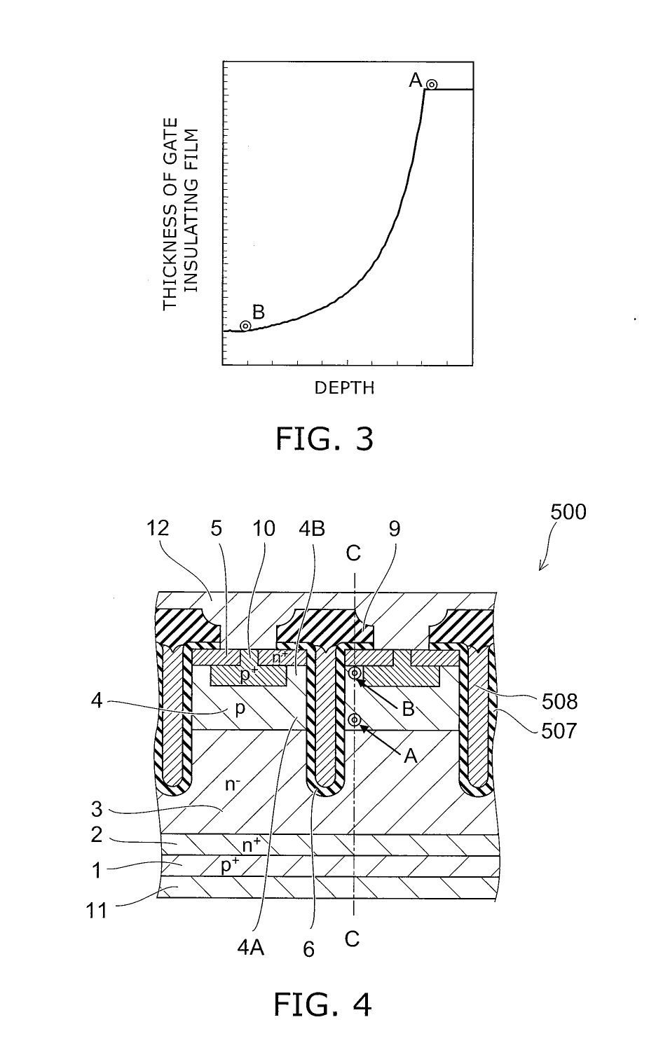

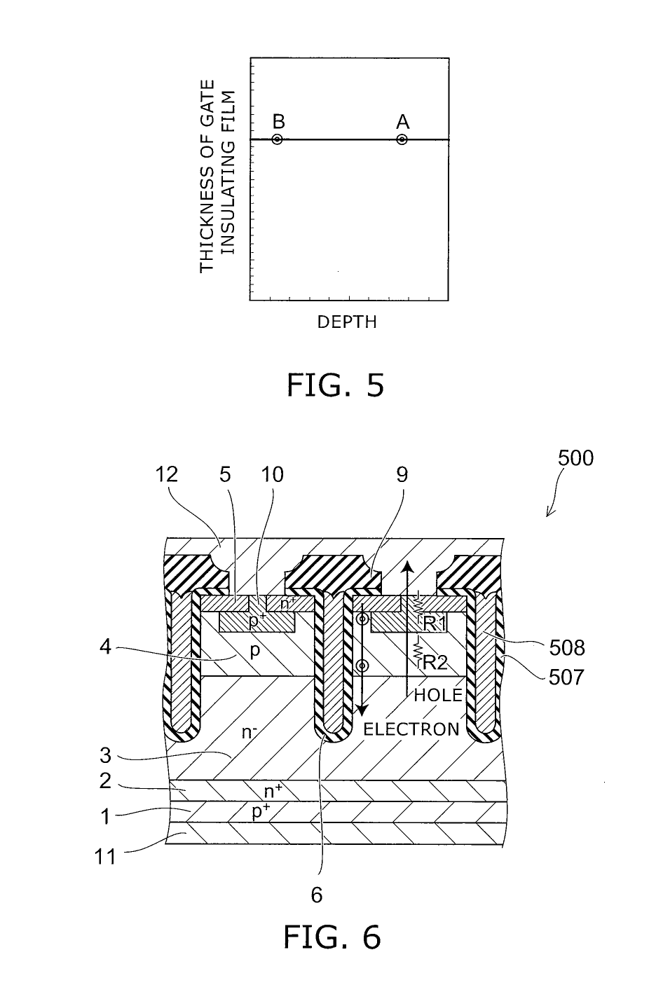

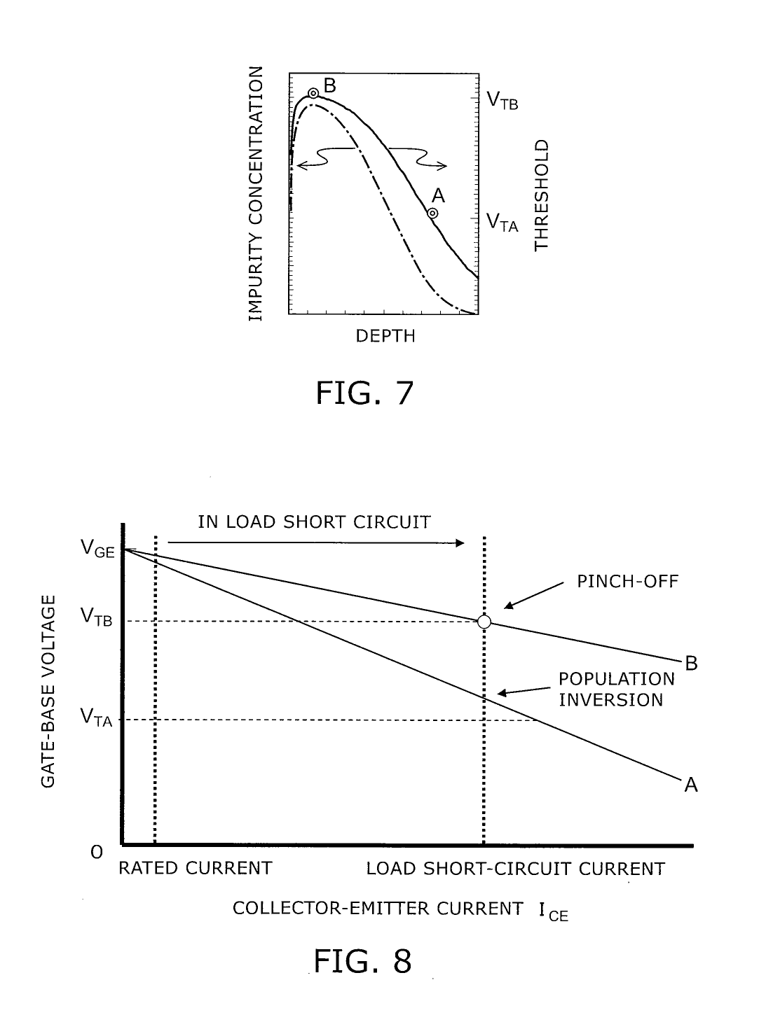

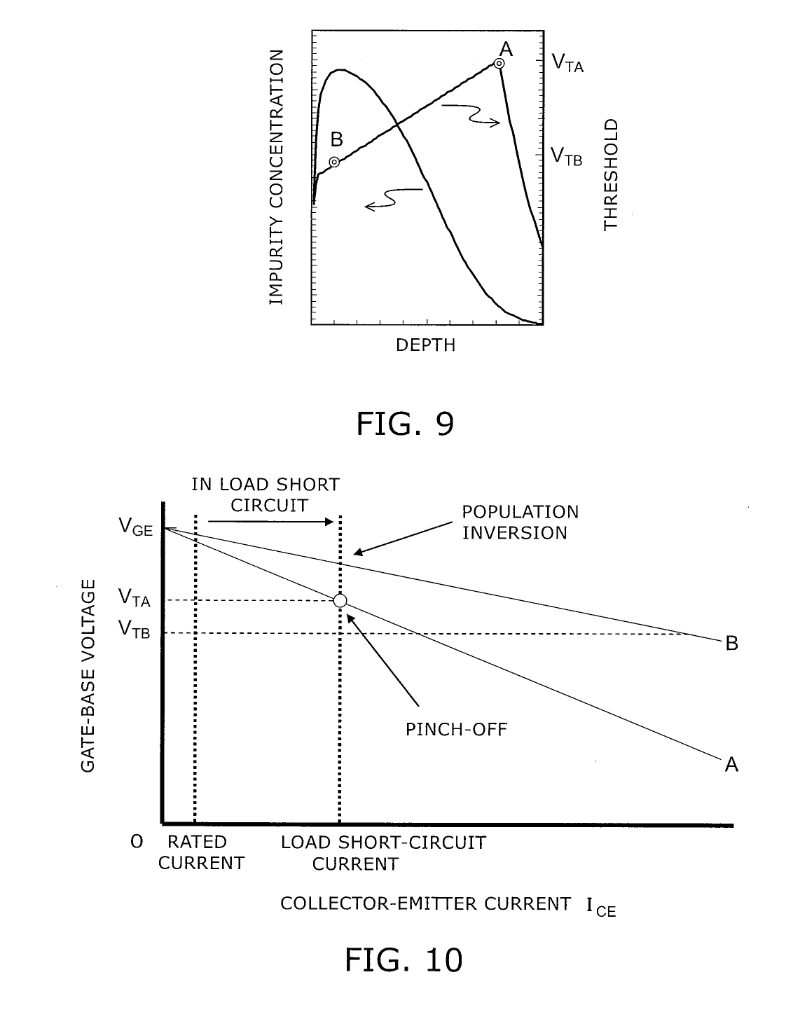

A first embodiment will now be described along with a comparative example using FIG. 1 to FIG. 10. FIG. 1 is a cross-sectional view of a main portion of a power semiconductor device according to the first embodiment. FIG. 2 is a graph showing the impurity concentration profile along line C-C of FIG. 1. FIG. 3 is a graph showing the change along the trench depth direction of the gate insulating film thickness of the power semiconductor device according to the first embodiment. FIG. 4 is a cross-sectional view of a main portion of a power semiconductor device according to a comparative example. FIG. 5 is a graph showing the change along the trench depth direction of the gate insulating film thickness of the power semiconductor device according to the comparative example. FIG. 6 is a cross-sectional view of a main portion for describing operations of the power semiconductor device according to the comparative example. FIG. 7 is a graph showing the profile of the p-type impurity concentration of a p-type base layer and the change in the depth direction of the threshold of the power semiconductor device according to the comparative example. FIG. 8 is a graph showing relationships between the gate-base voltage and the collector-emitter current of the power semiconductor device according to the comparative example. FIG. 9 is a graph showing the profile of the p-type impurity concentration of a p-type base layer and the change in the depth direction of the threshold of the power semiconductor device according to the first embodiment. FIG. 10 is a graph showing relationships between the gate-base voltage and the collector-emitter current of the power semiconductor device according to the first embodiment.

As shown in FIG. 1, a power semiconductor device 100 according to the first embodiment is an IGBT, and includes a p-type collector layer 1, an n⁺-type buffer layer 2, an n⁻-type base layer 3, a p-type base layer 4, an n⁺-type source layer 5, a gate electrode 8, an interlayer insulating film 9, a collector electrode 11, and an emitter electrode 12.

The n⁻-type base layer 3 is provided above the p⁺-type collector layer 1 via the n⁺-type buffer layer 2. The n⁻-type base layer 3 has an n-type impurity concentration lower than the n-type impurity concentration of the n⁺-type buffer layer 2. As an example, the layer structure of these can be formed by a method in which the n⁺-type buffer layer 2 and the n⁻-type base layer 3 are epitaxially grown using silicon in this order on a p⁺-type silicon substrate. Then, by grinding the p⁺-type substrate into a desired thickness, the p⁺-type substrate can be made into the p⁺-type collector layer.

The p-type base layer 4 is provided on the n⁻-type base layer 3. The n⁺-type source layer 5 has a higher n-type impurity concentration than the n⁻-type base layer 3, and is selectively formed on the surface of the p-type base layer 4. As shown in FIG. 2, the p-type base layer 4 has a p-type impurity concentration profile 4P in which the p-type impurity concentration has a maximum value in a portion 4B adjacent to the n⁺-type source layer 5 in the stacking direction (hereinafter an “upper end portion”), that is, in a portion entering from the surface of the p-type base layer 4 to the p⁺-type collector layer 1 side by an amount of the thickness with which the n⁺-type source layer 5 is formed, and the p-type impurity concentration decreases monotonically in an exponential manner with proximity to the p⁺-type collector layer 1. As an example, the p-type base layer 4 thus configured can be formed as a diffusion layer by ion-implanting a p-type impurity (e.g. boron etc.) into the surface of the n⁻-type base layer 3 under prescribed conditions and then performing heat treatment to thermally diffuse the p-type impurity.

A trench 6 is formed that runs from the surface of the n⁺-type source layer 5 through the n⁺-type source layer 5 and the p-type base layer 4 to the interior of the n⁻-type base layer 3. A gate insulating film 7 including a first portion 7A and a second portion 7B is provided so as to cover the bottom surface and side wall of the trench 6 and the surface of the n⁺-type source layer 5 around the opening of the trench 6. The first portion 7A of the gate insulating film 7 covers the surface of the n⁻-type base layer 3 exposed at the bottom surface and side wall of the trench 6 and the surface of a bottom end portion 4A of the p-type base layer 4 adjacent to the n⁻-type base layer 3. The second portion of the gate insulating film 7 covers the surface of the n⁺-type source layer 5 and the surface of the portion from the upper end portion 4B to the central portion of the p-type base layer 4 exposed at the side wall of the trench 6, and is continuous with the first portion 7A of the gate insulating film 7. The second portion 7B of the gate insulating film 7 has a thinner thickness than the first portion 7A of the gate insulating film 7 on the surface of the n⁺-type source layer 5 and the surface of the upper end portion 4B of the p-type base layer 4 of the side wall of the trench 6; becomes thicker exponentially with proximity to the bottom end portion 4A of the p-type base layer 4; and has a thickness equal to the film thickness of the first portion 7A of the gate insulating film 7 on the surface of the bottom end portion 4A of the p-type base layer 4. As shown in FIG. 2, the concentration of the p-type impurity in the p-type base layer 4 decreases exponentially from the depth B of the upper end portion 4B of the p-type base layer 4 toward the depth A of the bottom end portion 4A of the p-type base layer 4. As shown in FIG. 3, the film thickness of the second portion 7B of the gate insulating film 7 increases exponentially from the depth B of the upper end portion 4B of the p-type base layer 4 toward the depth A of the bottom end portion 4A of the p-type base layer 4 in accordance with the change of the p-type impurity concentration in the p-type base layer 4. The gate insulating film 7 may be silicon oxide for both the first portion 7A and the second portion 7B, or may be a dielectric film of silicon nitride, alumina, or the like or a stacked structure of them.

Similarly, also the gate electrode 8 includes a first portion 8A and a second portion 8B. The first portion 8A of the gate electrode 8 is embedded in the trench 6 via the first portion 7A of the gate insulating film 7. The second portion 8B of the gate electrode 8 is embedded in the trench 6 via the second portion 7B of the gate insulating film 7, and is continuous with the first portion 8A of the gate electrode 8.

The interlayer insulating film 9 is formed so as to cover the second portion 8B of the gate electrode 8 to insulate it from the emitter electrode 12 described later. The first portion 8A and the second portion 8B of the gate electrode 8 need at least to be the same highly conductive material, for example, may be polysilicon doped to be in n type conductivity. The gate electrode 8 is drawn out from a not-shown opening of the interlayer insulating film 9 to the outside of the trench 6, and is drawn out to a not-shown gate electrode terminal by a not-shown gate interconnection layer and a not-shown gate electrode pad. The interlayer insulating film 9 may be silicon oxide, silicon nitride, alumina, or a stacked structure of them similarly to the gate insulating film.

The collector electrode 11 is formed on the surface of the p⁺-type collector layer 1 on the opposite side to the n⁻-type base layer 3, and is electrically connected to the p⁺-type collector layer 1. Also the collector electrode 11 is drawn out to a collector electrode terminal by a not-shown interconnection.

A p⁺-type contact layer 10 is formed in a portion adjacent to the n⁺-type source layer 5 of the surface of the p-type base layer 4. The p⁺-type contact layer 10 has a p-type impurity concentration higher than the p-type impurity concentration of the p-type base layer 4. The emitter electrode 12 is formed on the surfaces of the n⁺-type source layer 5 and the p⁺-type contact layer 10 via a not-shown opening of the interlayer insulating film 9. The emitter electrode 12 is electrically connected to the n⁺-type source layer 5, and is electrically connected to the p-type base layer 4 via the p⁺-type contact layer 10. The p⁺-type contact layer 10 is a layer provided in order to electrically connect the emitter electrode 12 and the p-type base layer 4 in good condition. Even if the emitter electrode 12 is formed directly on the surface of the p-type base layer 4 without interposing the p⁺-type contact layer 10, only the contact resistance increases. Also such a structure is within the scope of the technical idea of the invention because the effect of the invention is similarly obtained.

Before describing operations of the IGBT 100 according to the embodiment and effects of the invention, the structure and operations of an IGBT 500 according to the comparative example are described. FIG. 4 is a cross-sectional view of a main portion of the IGBT according to the comparative example. The IGBT 500 according to the comparative example has the same structure as the IGBT 100 according to the embodiment except that a gate insulating film 507 formed so as to cover the bottom surface and side wall of the trench 6 has a uniform thickness. That is, in the IGBT 500 according to the comparative example, the gate insulating film 507 and a gate electrode 508 do not have a structure including the first portion and the second portion, but have a single uniform structure. Also the impurity concentration profile along line C-C from the depth B of the upper end portion 4B of the p-type base layer 4 to the depth A of the bottom end portion 4A of the p-type base layer 4 in FIG. 4 is similar to that shown in FIG. 2. FIG. 5 shows the change in the depth direction of the gate insulating film of the IGBT 500 according to the comparative example. As shown in FIG. 5, the gate insulating film 507 is uniformly formed in the entire region of the bottom surface and side wall of the trench.

Operations of the IGBT 500 according to the comparative example will now be described. When the rated voltage V_{GE} exceeding the threshold of the ON/OFF state of the IGBT is applied to the gate electrode 508 with respect to the emitter electrode 12 in a condition where a positive voltage is applied to the collector electrode 11 with respect to the emitter electrode 12, a population inversion layer of electrons is formed between the p-type base layer 4 and the gate insulating film 508. At this time, as shown in FIG. 6, electrons are injected from the emitter electrode 12 into the n⁻-type base layer 3 through the n⁺-type source layer 5 and the population inversion layer of the p-type base layer 4, and then the portion between the n⁻-type base layer 3 and the p⁺-type collector layer 1 becomes to be in forward bias. Holes are injected from the p⁺-type collector layer 1 into the n⁻-type base layer 3; and in the n⁻-type base layer 3, the numbers of electrons and holes increase rapidly to cause a conductivity modulation. As a result, the resistance value of the n⁻-type base layer 3 decreases rapidly, and the IGBT 500 is turned to the ON state. In the ON state, electrons flow from the emitter electrode 12 to the collector electrode 11 through the n⁺-type source layer 5, the population inversion layer of the p-type base layer 4, the n⁻-type base layer 3, and the p⁺-type collector layer 1. Holes flow to the emitter electrode 12 through the collector electrode 11, the p⁺-type collector layer 1, the n⁻-type base layer 3, the p-type base layer 4, and the p⁺-type contact layer 10.

Here, as shown in FIG. 7, the concentration of the p-type impurity in the p-type base layer 4 has a maximum in the upper end portion 4B (point B in the drawing) of the p-type base layer 4, and decreases with proximity to the bottom portion 4A (A in the drawing) of the p-type base layer 4. In general, as the p-type impurity concentration of the p-type base layer increases, a population inversion layer is less likely to be formed between the p-type base layer and the gate insulating film. That is, a population inversion layer is formed when the voltage applied between the gate electrode and the p-type base layer exceeds the threshold; and here, the threshold for population inversion layer formation increases as the p-type impurity concentration of the p-type base layer increases. In the case where there are a plurality of portions with different thresholds for population inversion layer formation in the direction in which electrons of the population inversion layer are propagated (the direction of the channel length), the threshold of the ON/OFF state of the IGBT is the highest threshold out of the thresholds for population inversion layer formation. That is, the IGBT is turned to the ON state when the voltage applied between the gate electrode and the p-type base layer exceeds the highest threshold for population inversion layer formation.

In the IGBT 500 according to the comparative example, as shown in FIG. 7, the threshold of the population inversion layer has a maximum in the upper end portion 4B of the p-type base layer 4, and has a minimum in the bottom end portion 4A of the p-type base layer 4. Therefore, the IGBT 500 has the threshold of the upper end portion 4B of the p-type base layer 4 as the threshold of the ON/OFF state of the IGBT. Here, when the thresholds for population inversion layer formation in the upper end portion 4B and the bottom end portion 4A of the p-type base layer 4 are denoted by V_{TB} and V_{TA}, respectively, the IGBT 500 is in the ON state in conditions where the voltage between the gate electrode 508 and the p-type base layer 4 is higher than V_{TB}, and the IGBT 500 is in the OFF state in conditions where it is lower than V_{TB} and higher than V_{TA}. In the latter OFF state, in the upper end portion 4B of the p-type base layer 4, the population inversion layer disappears to cause pinch-off; and in the bottom end portion 4A of the p-type base layer 4, the population inversion layer exists. At this time, the pinch-off point exists between the upper end portion 4B and the bottom end portion 4A of the p-type base layer 4, and the voltage applied between the gate electrode 508 and the p-type base layer 4 in this portion is the pinch-off voltage.

Next, the case is considered where a load short circuit occurs on the load side in the ON state where the rated voltage V_{GE} sufficiently larger than the threshold V_{TA} of the IGBT is applied to the gate electrode 508. If a load short circuit occurs, the large voltage that has been applied to the load is applied between the collector electrode 11 and the emitter electrode 12 of the IGBT 500, and therefore a large current of the load short circuit current flows between collector and emitter instantaneously. The load short-circuit current due to holes flows through the p-type base layer 4 and the p⁺-type contact layer 10 to cause voltage drops V_{A} and V₈ in the respective layers as shown in FIG. 6. When the internal resistances of the p-type base layer 4 and the p⁺-type contact layer 10 are denoted by R2 and R1, respectively, R2>>R1 holds because the p-type impurity concentration in the p-type base layer 4 has the impurity concentration profiles shown in FIG. 2 and FIG. 7 and the p⁺-type contact layer 10 has a concentration still higher than the maximum value of the p-type impurity concentration of the p-type base layer 4. When the collector-emitter current is denoted by I_{CE}, then V_{A}=R2×I_{CE} and V_{B}=R1×I_{CE}; and in the upper end portion 4B of the p-type base layer 4, the voltage applied between the gate electrode 508 and the p-type base layer 4 is V_{GE}−V_{B}. In the bottom end portion 4A of the p-type base layer 4, the voltage applied between the gate electrode 508 and the p-type base layer 4 is V_{GE}−(V_{A}+V_{B}).

FIG. 8 shows a graph in which the voltage applied between the gate electrode and the p-type base layer (hereinafter the “gate-base voltage”) decreases due to the collector-emitter current with regard to the upper end portion 4B (B in the drawing) and the bottom end portion 4A (A in the drawing) of the p-type base layer 4. When the rated current flows between the collector and the emitter of the IGBT 500, the IGBT 500 is in a stable ON state because the gate-base voltage is less affected by the voltage drop caused by the hole current and is sufficiently larger than the thresholds V_{TB} and V_{TA} for population inversion layer formation of the upper end portion 4B and the bottom end portion 4A of the p-type base layer 4. Here, if a load short circuit occurs, the collector-emitter current increases rapidly, and the gate-base voltage decreases rapidly. Since the voltage drop due to the hole current is larger in the bottom end portion 4A of the p-type base layer 4 than in the upper end portion 4B, the gate-base voltage decreases more rapidly in the bottom end portion 4A of the p-type base layer 4. However, since the threshold V_{TB} for population inversion layer formation of the upper end portion 4B of the p-type base layer 4 is higher than that of the bottom end portion 4A, the gate-base voltage reaches the threshold V_{TB} for population inversion layer formation of the upper end portion 4B of the p-type base layer 4 earlier, and the upper end portion 4B of the p-type base layer 4 becomes the pinch-off state earlier. Consequently, the collector-emitter current I_{CE} of the IGBT 500 is fixed to the saturation current of the pinch-off, and this is the load short-circuit current. As the saturation current due to the pinch-off is reduced to a lower level, the load short-circuit withstand capability of the IGBT 500 can be increased.

Next, operations of the IGBT 100 according to the embodiment when a load short circuit occurs are described similarly to the foregoing. FIG. 9 shows the profile of the p-type impurity concentration in the p-type base layer (similar to FIG. 2 and FIG. 7) and the change in the depth direction of the threshold for population inversion layer formation of the IGBT 100 according to the embodiment. The film thickness of the gate insulating film 7 of the IGBT 100 according to the embodiment is increased in accordance with the decrease of the p-type impurity concentration as shown in FIG. 3. In general, as the gate insulating film is made thicker, a population inversion layer between the gate insulating film and the p-type base layer is less likely to be formed; therefore, the threshold for population inversion layer formation increases. In the embodiment, the gate insulating film 7 is formed such that the film thickness of the first portion 7A of the gate insulating film 7 for the bottom end portion 4A of the p-type semiconductor layer 4 is thicker than the film thickness of the second portion 7B of the gate insulating film 7 for the upper end portion 4B of the p-type semiconductor layer 4 in such a manner that the increase in threshold due to the increase of gate insulating film thickness can be obtained in an amount not less than the amount of the decrease in threshold for population inversion layer formation due to the decrease of p-type impurity concentration. As a consequence, as shown in FIG. 9, the threshold V_{TA} in the bottom end portion 4A of the p-type base layer 4 is higher than the threshold V_{TB} in the upper end portion 4B.

In the IGBT 100 according to the embodiment, unlike the IGBT 500 according to the comparative example, the threshold V_{TA} for population inversion layer formation in the bottom end portion 4A of the p-type base layer 4 is higher than the threshold V_{TB} for population inversion layer formation in the upper end portion 4B. Consequently, as shown in FIG. 10, if a load short circuit occurs on the load side of the IGBT 100 according to the embodiment, pinch-off occurs earlier in the bottom end portion 4A of the p-type base layer 4 than in the upper end portion 4B, and the saturation current due to the pinch-off at this time is the load short-circuit current. Consequently, the IGBT 100 according to the embodiment has a significantly lower load short-circuit current than the IGBT 500 according to the comparative example, and therefore has a significantly higher load short-circuit withstand capability.

As described above, in the IGBT 100 according to the embodiment, the gate electrode 8 includes the first portion 8A and the second portion 8B. The first portion 8A is opposed to the n⁻-type base layer 3 and the bottom end portion 4A of the p-type base layer 4 via the first portion 7A of the gate insulating film 7. The second portion 8B is continuous with the upper portion of the first portion 8A of the gate electrode 8 and is opposed to the upper end portion 4B of the p-type base layer 4 and the n⁺-type source layer 5 via the second portion 7B of the gate insulating film 7. The gate electrode 8 is formed such that the threshold V_{TA} at which a population inversion layer is formed between the first portion 7A of the gate insulating film 7 and the bottom end portion 4A of the p-type base layer 4 is not less than the threshold V_{TB} at which a population inversion layer is formed between the second portion 7B of the gate insulating film 7 and the upper end portion 4B of the p-type base layer 4. Thereby, pinch-off occurs earlier in the bottom end portion 4A of the p-type base layer 4 than in the upper end portion 4B, and the IGBT 100 according to the embodiment has a high load short-circuit withstand capability while having a low ON resistance.

In particular, in the embodiment, the gate electrode 8 is formed in the trench 6 via the gate insulating film 7 in which the film thickness of the first portion 7A of the gate insulating film 7 is made thicker than the film thickness of the second portion 7B. Thereby, the threshold V_{TA} at which a population inversion layer is formed between the first portion 7A of the gate insulating film 7 and the bottom end portion 4A of the p-type base layer 4 is made not less than the threshold V_{TB} at which a population inversion layer is formed between the second portion 7B of the gate insulating film 7 and the upper end portion 4B of the p-type base layer 4.

Although the IGBT 100 according to the embodiment includes the n⁺-type buffer layer 2 between the p⁺-type collector layer 1 and the n⁻-type base layer 3, the n⁺-type buffer layer 2 may be omitted in a structure in which the n⁻-type base layer 3 is sufficiently thick and the depletion layer extends from the p-type base layer 4 but does not reach to the p⁺-type collector layer 1.

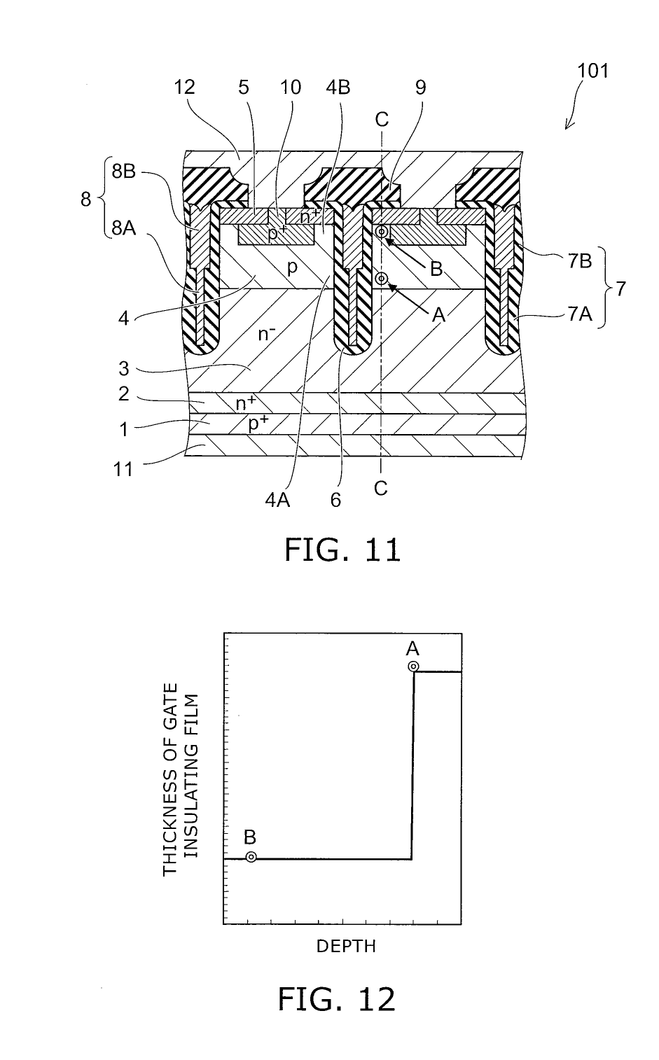

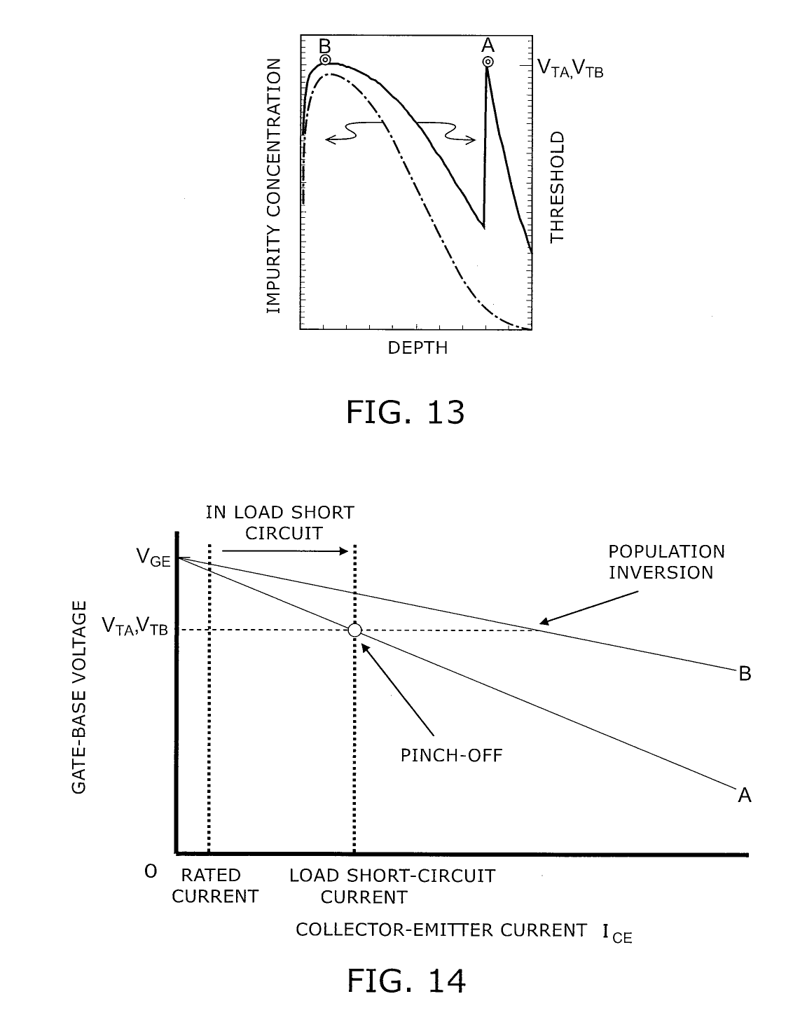

Next, an IGBT 101 according to a modification example of the embodiment is described using FIG. 11. FIG. 11 is a cross-sectional view of a main portion of the IGBT 101 according to the modification example of the embodiment. FIG. 12 is a graph showing the change along the trench depth direction of the gate insulating film thickness of the IGBT 101 according to the modification example of the embodiment. FIG. 13 is a graph showing the profile of the p-type impurity concentration of the p-type base layer and the change in the depth direction of the threshold of the IGBT 101 according to the modification example of the embodiment. FIG. 14 is a graph showing relationships between the igate-base voltage and the collector-emitter current of the IGBT 101 according to the modification example of the embodiment.

In the IGBT 100 of the first embodiment, the film thickness of the second portion 7B of the gate insulating film 7 increases exponentially from the depth B of the upper end portion 4B of the p-type base layer 4 toward the depth A of the bottom end portion 4A of the p-type base layer 4 in accordance with the change of the p-type impurity concentration in the p-type base layer 4. In contrast, as shown in FIG. 11 and FIG. 12, in the IGBT 101 according to the modification example of the embodiment, the second portion 7B of the gate insulating film 7 has a fixed film thickness irrespective of the p-type impurity concentration in the p-type base layer 4, and is formed thinner than the film thickness of the first portion 7A. Otherwise, the IGBT 101 according to the modification example has the same structure as the IGBT 100 according to the embodiment.

Also in the modification example, by making the thickness of the first portion 7A of the gate insulating film 7 thicker than the thickness of the second portion 7B of the gate insulating film 7, the threshold V_{TA} for population inversion layer formation of the first portion 7A is set at a high level. However, whereas in the IGBT 100 according to the embodiment the threshold V_{TA} for population inversion layer formation in the first portion 7A is made higher than the threshold V_{TB} for population inversion layer formation in the second portion 7B, as shown in FIG. 13, in the IGBT 101 according to the modification example the threshold V_{TA} for population inversion layer formation in the first portion 7A and the threshold V_{TB} for population inversion layer formation in the second portion 7B are set almost equal. Also by such a configuration, as shown in FIG. 14 in which the situation of pinch-off at the time of a load short circuit is shown, in the IGBT 101 according to the modification example, the bottom end portion 4A of the p-type base layer 4 becomes the pinch-off state earlier than the upper end portion 4B, and therefore the saturation current value decreases and the load short-circuit current can be reduced. Consequently, the load short-circuit withstand capability is improved.

Also in the IGBT 101 according to the modification example, the gate electrode 8 is formed such that the threshold V_{TA} at which a population inversion layer is formed between the first portion 7A of the gate insulating film 7 and the bottom end portion 4A of the p-type base layer 4 is not less than the threshold V_{TB} at which a population inversion layer is formed between the second portion 7B of the gate insulating film 7 and the upper end portion 4B of the p-type base layer 4. Thereby, pinch-off occurs earlier in the bottom end portion 4A of the p-type base layer 4 than in the upper end portion 4B, and the IGBT 101 according to the modification example has a high load short-circuit withstand capability while having a low ON resistance.

In the IGBT 100 according to the embodiment and the IGBT 101 according to the modification example, the gate electrode 8 is formed in the trench 6 via the gate insulating film 7 in which the film thickness of the first portion 7A of the gate insulating film 7 is made thicker than the film thickness of the second portion 7B. Thereby, the threshold V_{TA} at which a population inversion layer is formed between the first portion 7A of the gate insulating film 7 and the bottom end portion 4A of the p-type base layer 4 is made not less than the threshold V_{TB} at which a population inversion layer is formed between the second portion 7B of the gate insulating film 7 and the upper end portion 4B of the p-type base layer 4.

In contrast, details omitted, the effects of the embodiment and the modification example mentioned above can be obtained also by a configuration in which the first portion 7A of the gate insulating film 7 has the same film thickness as the second portion 7B but is made of a dielectric having a dielectric constant lower than the dielectric constant of the second portion. For example, the first portion 7A of the gate insulating film 7 may be silicon oxide, and the second portion 7B may be silicon nitride. As a matter of course, it is possible to use both of making the film thickness of the first portion 7A of the gate insulating film 7 thicker than the film thickness of the second portion 7B and selecting the dielectric materials of the first portion 7A and the second portion 7B such that the dielectric constant of the first portion 7A is lower than the dielectric constant of the second portion 7B.

### Second Embodiment

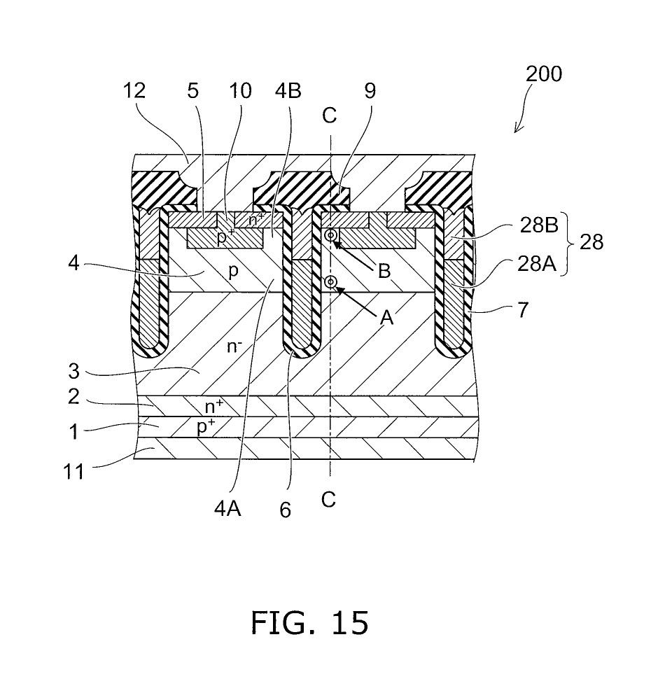

Next, an IGBT 200 according to a second embodiment is described using FIG. 15. FIG. 15 is a cross-sectional view of a main portion of the IGBT 200 according to the embodiment. Portions with configurations identical to the configurations described in the first embodiment are indicated by the same reference numerals or symbols, and a description thereof is omitted. Differences from the first embodiment are mainly described.

As shown in FIG. 15, the IGBT 200 according to the embodiment differs from the IGBT 100 according to the first embodiment in that the first portion 7A and the second portion 7B of the gate insulating film 7 are formed of the same dielectric film and with the same thickness and in that the first portion of the gate electrode 8 is formed so as to have a lower Fermi level than the second portion in the IGBT 100 according to the first embodiment. Otherwise, the IGBT 200 has the same structure as the IGBT 100.

The threshold Vₜₕ for population inversion layer formation is generally expressed by Formula (I) below, where V_{FB} is the flat band voltage and V_{FB}=(E_{F}−E_{FM})/q, E_{F} is the Fermi level of the p-type base layer, E_{FM} is the Fermi level of the gate electrode, and q is the elementary charge. ψ_{B}=(Eᵢ−E_{F})/q, and Eᵢ is the intrinsic Fermi level of the p-type base layer. ∈ₛ is the dielectric constant of silicon, N_{A} is the acceptor density, and C_{O} is the capacitance of the gate insulating film.

$${V}_{th} = {V}_{FB} + 2 {ψ}_{B} + \frac{\sqrt{2 {ɛ}_{s} {qN}_{A} 2 {ψ}_{B}}}{{C}_{O}} \qquad ( 1 )$$

As the Fermi level E_{FM} of the gate electrode increases (the energy level increases), V_{FB} increases in negative value and therefore Vₜₕ decreases from Formula (I). Thus, by setting the Fermi level E_{FM} of the first portion 8A of the gate electrode 8 lower than the Fermi level E_{FM} of the second portion 8B, the threshold V_{TA} at which a population inversion layer is formed between the first portion 7A of the gate insulating film 7 and the bottom end portion 4A of the p-type base layer 4 can be set higher than the threshold V_{TB} at which a population inversion layer is formed between the second portion 7B of the gate insulating film 7 and the upper end portion 4B of the p-type base layer 4.

As shown in FIG. 7, the p-type impurity concentration of the p-type base layer 4 decreases exponentially from the upper end portion 4B of the p-type base layer 4 toward the bottom end portion 4A; consequently, the threshold V_{TA} at which a population inversion layer is formed between the first portion 7A of the gate insulating film 7 and the bottom end portion 4A of the p-type base layer 4 is lower than the threshold V_{TB} at which a population inversion layer is formed between the second portion 7B of the gate insulating film 7 and the upper end portion 4B of the p-type base layer 4. In view of this, in the IGBT 200 according to the embodiment, the Fermi level E_{FM} of the first portion 8A of the gate electrode 8 is set lower than the Fermi level E_{FM} of the second portion 8B so that the influence of the p-type impurity concentration in the p-type base layer 4 mentioned above on the threshold for population inversion layer formation may be canceled, and further so that the threshold V_{TA} at which a population inversion layer is formed between the first portion 7A of the gate insulating film 7 and the bottom end portion 4A of the p-type base layer 4 may be not less than the threshold V_{TB} at which a population inversion layer is formed between the second portion 7B of the gate insulating film 7 and the upper end portion 4B of the p-type base layer 4.

By setting the Fermi levels of the first portion 8A and the second portion 8B of the gate electrode 8 in the above way, similar effects to the first embodiment or the modification example thereof can be obtained as shown in FIG. 10 or FIG. 14.

As an example of the gate electrode 8 in which the Fermi level E_{FM} of the first portion 8A of the gate electrode 8 is lower than the Fermi level E_{FM} of the second portion 8B, a configuration is given in which the first portion of the gate electrode 8 is made of polysilicon doped to be in a p type conductivity and the second portion of the gate electrode 8 is made of polysilicon doped to be in an n type conductivity. When the first portion 8A and the second portion 8B of the gate electrode 8 are a p-type semiconductor and an n-type semiconductor, respectively, a highly conductive semiconductor layer other than polysilicon may be used for the first portion 8A and the second portion 8B of the gate electrode 8.

Alternatively, it is also possible to use a configuration in which the first portion 8A of the gate electrode 8 is formed of a first semiconductor layer, the second portion 8B is formed of a second semiconductor layer, and the electron affinity of the first semiconductor layer is larger than the electron affinity of the second semiconductor layer. Thereby, the gate electrode 8 can be obtained in which the Fermi level E_{FM} of the first portion 8A of the gate electrode 8 is lower than the Fermi level E_{FM} of the second portion 8B. For example, an n-type polysilicon may be used as the first semiconductor, and an n-type silicon carbide (SiC) may be used as the second semiconductor. Furthermore, by making the first semiconductor a p type and the second semiconductor an n type in the above way, the Fermi level of the first portion 8A of the gate electrode 8 can be made still lower than that of the second portion 8B.

As described above, also in the IGBT 200 according to the embodiment, similarly to the IGBT 100 according to the first embodiment, the gate electrode 8 includes the first portion 8A that is opposed to the n⁻-type base layer 3 and the bottom end portion 4A of the p-type base layer 4 via the first portion 7A of the gate insulating film 7 and the second portion 8B that is continuous with the upper portion of the first portion 8A of the gate electrode 8 and is opposed to the upper end portion 4B of the p-type base layer 4 and the n⁺-type source layer 5 via the second portion 7B of the gate insulating film 7. The gate electrode 8 is formed such that the threshold V_{TA} at which a population inversion layer is formed between the first portion 7A of the gate insulating film 7 and the bottom end portion 4A of the p-type base layer 4 is not less than the threshold V_{TB} at which a population inversion layer is formed between the second portion 7B of the gate insulating film 7 and the upper end portion 4B of the p-type base layer 4. Thereby, pinch-off occurs earlier in the bottom end portion 4A of the p-type base layer 4 than in the upper end portion 4B, and the IGBT 200 according to the embodiment has a high load short-circuit withstand capability while having a low ON resistance.

In particular, in the embodiment, the gate electrode 8 is formed in the trench 6 via the gate insulating film 7 such that the Fermi level E_{FM} of the first portion 8A of the gate electrode 8 is lower than the Fermi level E_{FM} of the second portion 8B. Thereby, the threshold V_{TA} at which a population inversion layer is formed between the first portion 7A of the gate insulating film 7 and the bottom end portion 4A of the p-type base layer 4 is made not less than the threshold V_{TB} at which a population inversion layer is formed between the second portion 7B of the gate insulating film 7 and the upper end portion 4B of the p-type base layer 4.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power semiconductor device comprising:
a p-type collector layer;
an n-type base layer formed on the p-type collector layer;
a p-type base layer formed on the n-type base layer;
an n-type source layer selectively formed on a surface of the p-type base layer and having a higher n-type impurity concentration than the n-type base layer;
a gate electrode formed in a trench running from a surface of the n-type source layer through the n-type source layer and the p-type base layer to an interior of the n-type base layer via a gate insulating film;
an interlayer insulating film formed on the gate electrode;
a collector electrode electrically connected to a surface of the p-type collector layer on an opposite side to the n-type source layer; and
an emitter electrode electrically connected to the n-type source layer and the p-type base layer via an opening provided in the interlayer insulating film,
an impurity concentration of the p-type base layer having a maximum in an upper end portion adjacent to the source layer and decreasing from the upper end portion of the p-type base layer toward the n-type base layer in a stacking direction,
the gate electrode including:
a first portion opposed to the n-type base layer and a bottom end portion of the p-type base layer via a first portion of the gate insulating film; and
a second portion continuous with an upper portion of the first portion of the gate electrode and opposed to the upper end portion of the p-type base layer and the n-type source layer via a second portion of the gate insulating film,
the gate electrode being formed such that a threshold for a population inversion layer to be formed between the first portion of the gate insulating film and the bottom end portion of the p-type base layer is not less than a threshold for a population inversion layer to be formed between the second portion of the gate insulating film and the upper end portion of the p-type base layer.

2. The device according to claim 1, wherein the p-type base layer is a diffusion layer selectively formed on a surface of the n-type base layer.

3. The device according to claim 1, wherein the emitter electrode is electrically connected to the p-type base layer via a p-type contact layer formed on a surface of the p-type base layer, the p-type contact layer having a p-type impurity concentration higher than a concentration of a p-type impurity of the p-type base layer.

4. The device according to claim 1, wherein a film thickness of the first portion of the gate insulating film is thicker than a film thickness of the second portion of the gate insulating film.

5. The device according to claim 4, wherein a film thickness of the second portion of the gate insulating film increases with proximity to the first portion of the gate insulating film.

6. The device according to claim 1, wherein the first portion of the gate insulating film is made of a material having a dielectric constant lower than a dielectric constant of the second portion of the gate insulating film.

7. The device according to claim 1, wherein a Fermi level of the first portion of the gate electrode is lower than a Fermi level of the second portion of the gate electrode.

8. The device according to claim 7, wherein
the first portion of the gate electrode is p-type polysilicon and
the second portion of the gate electrode is n-type polysilicon.

9. The device according to claim 7, wherein
the first portion of the gate electrode is a p-type semiconductor layer and
the second portion of the gate electrode is an n-type semiconductor layer.

10. The device according to claim 7, wherein
the first portion of the gate electrode is a first semiconductor layer,
the second portion of the gate electrode is a second semiconductor layer, and
an electron affinity of the first semiconductor layer is larger than an electron affinity of the second semiconductor layer.

11. The device according to claim 9, wherein
the first portion of the gate electrode is a first semiconductor layer,
the second portion of the gate electrode is a second semiconductor layer, and
an electron affinity of the first semiconductor layer is larger than an electron affinity of the second semiconductor layer.
